(19) United States
(12) Patent Application Publication
(10) Pub. No.: US 2018/0203493 A1
(43) Pub. Date: Jul. 19, 2018

(54) HEAT DISSIPATION CONTROL DEVICE BASED ON GRAPHICS CARD CORE PARAMETERS

(71) Applicant: EVGA CORPORATION, New Taipei City (TW)

(72) Inventor: Tai-Sheng Han, New Taipei City (TW)

(21) Appl. No.: 15/475,158

(22) Filed: Mar. 31, 2017

(30) Foreign Application Priority Data
Jan. 16, 2017 (TW) 106200781

(51) Int. Cl. G06F 1/20; H05K 7/20

(52) U.S. Cl. CPC G06F 1/206; H05K 7/20209; H05K 7/20172

(57) ABSTRACT

Disclosed is a head dissipation control device based on graphics card core parameters, including a graphics card, a cooling element arranged at one side of the graphics card, a control board arranged at one side of the cooling element and electrically connected with the cooling element, a graphics processor arranged on the graphics card, a detection unit provided in the control board, and at least one computation unit provided in the control board and in information communication with the detection unit. The detection unit reads and access chip specification of the graphics processor and detect a power consumption parameter of the graphics processor. The computation unit integrates the chip specification and the power consumption parameter to generate an optimum operation speed of the cooling element. A user may operate the control board to adjust the cooling element according to the operation speed so as to achieve an optimum cooling efficiency.

### (a) TECHNICAL FIELD OF THE INVENTION

The present invention relates generally to a heat dissipation control device based on graphics card core parameters, and more particularly to a heat dissipation control device based on graphics card core parameters, which achieves adjustment of a cooling element to an optimum operation speed according to parameters of a graphics card.

### (b) DESCRIPTION OF THE PRIOR ART

With the progress of technology and science, human beings invented various sorts of tool to make living easy and convenient. Among these tools, the invention of computers makes a great change to the living of human beings. The computers allow people to easily and conveniently upload and/or download data, providing people with a channel for easy acquirement of information, leading human beings into the era of information explosion, and providing the modern people with more ways of entertainment, such as watching movies, listening music, and playing games. A graphics card is an important device that allows human being to intact with the computer. The graphics card may make conversion of data that are necessary for a computer system and drives a display device and to supply scan signals in a one by one manner or for alternate lines to control the display device to make correct displaying, and is thus an important component connecting the display device and a main board of a personal computer. However, the operation of the graphics card may generate excessive heat. If the temperature of the graphics card gets high, the operation of the graphics card becomes unstable and the graphics card may even get down and stop functioning. Thus, it is common to provide a cooling element, such as a fan, on the graphics card to lower down the temperature of the graphics card and to keep the graphics card in normal operation. Further, to allow the cooling element to achieve the best performance, a control device that is capable of detecting a temperature may be arranged on the graphics card so as to make the graphics card in a normal operation by adjusting an operation speed of the cooling element according to the temperature of the graphics card and to prevent the operation speed of the cooling element from getting excessively fast or slow due to variations of power consumption parameters involved in the operation of the graphics card.

However, the conventional control device, when put into use, suffer certain problems that may need further improvements:

The heat dissipation device may only detect a temperature of a graphics card and is not allowed to conduct adjustment of the cooling element according a status of operation of the graphics card and cannot efficiently adjust the cooling element to provide the best performance, and is thus a solution that cannot completely overcome the problems.

Thus, it is a challenge of those devoted in this field to provide a solution to overcome such problems.

### SUMMARY OF THE INVENTION

In view of the above problems and drawbacks, the present invention aims to provide a heat dissipation control device based on graphics card core parameters, which achieves adjustment of a cooling element to an optimum operation speed according to parameters of a graphics card.

The primary objective of the present invention is to provide an arrangement of a detection unit and a computation unit to read and access chip specification of a graphics chip provided on a graphics card and to detect a power consumption parameter of the graphics processor, and then to integrate the chip specification and the power consumption parameter to generate an optimum operation speed of the cooling element.

Another objective of the present invention is to provide an arrangement of a control board and a cooling element, which conduct an adjustment of the cooling element according to an optimum operation speed of the cooling element generated by a computation unit in order to efficiently dissipate heat from a graphics card.

A structure that the present invention adopts to achieve the above objective generally comprises a graphics card, at least one cooling element arranged at one side of the graphics card for cooling the graphics card, at least one control board arranged at one side of the cooling element and in electrical connection with the cooling element for controlling an operation speed of the cooling element, at least one graphics processor provided on the graphics card, at least one detection unit provided in the control board, and at least one computation unit provided in the control board and in information communication with the detection unit, wherein the detection unit reads and access chip specification of the graphics processor and detects a power consumption parameter of the graphics processor. The computation unit generates an optimum operation speed of the cooling element according to the chip specification and the power consumption parameter and a user may operate the control board to adjust the cooling element according to the operation speed so as to efficiently dissipate heat from the graphics card.

Through the above technique, the problems and drawbacks of the prior art control device that a cooling element can only be adjusted based on a detected temperature of a graphics card and the cooling element cannot be adjusted to the best performance according to a status of use of the graphics card can be overcome and the present invention provides advantages of utilization as described above.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view showing a preferred embodiment of the present invention.

FIG. 2 is an exploded view of the preferred embodiment of the present invention.

FIG. 3 is a structure block diagram of the preferred embodiment of the present invention.

FIG. 4 is a schematic view illustrating an operation of a computation unit of the preferred embodiment of the present invention.

FIG. 5 is a schematic view showing an application of the preferred embodiment of the present invention.

FIG. 6 is a plot demonstrating rotational speed conversion conducted according the preferred embodiment of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

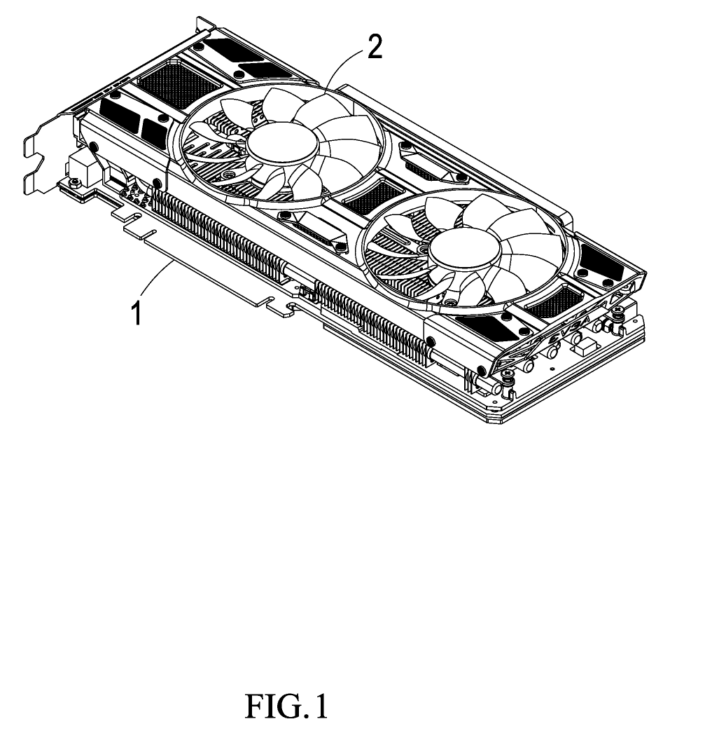

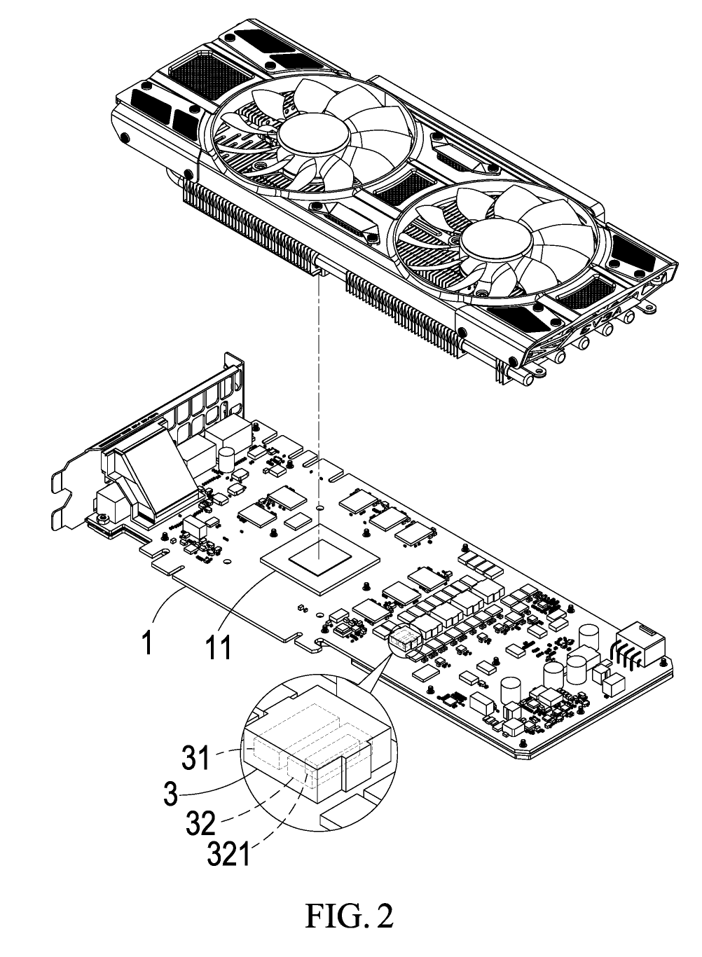

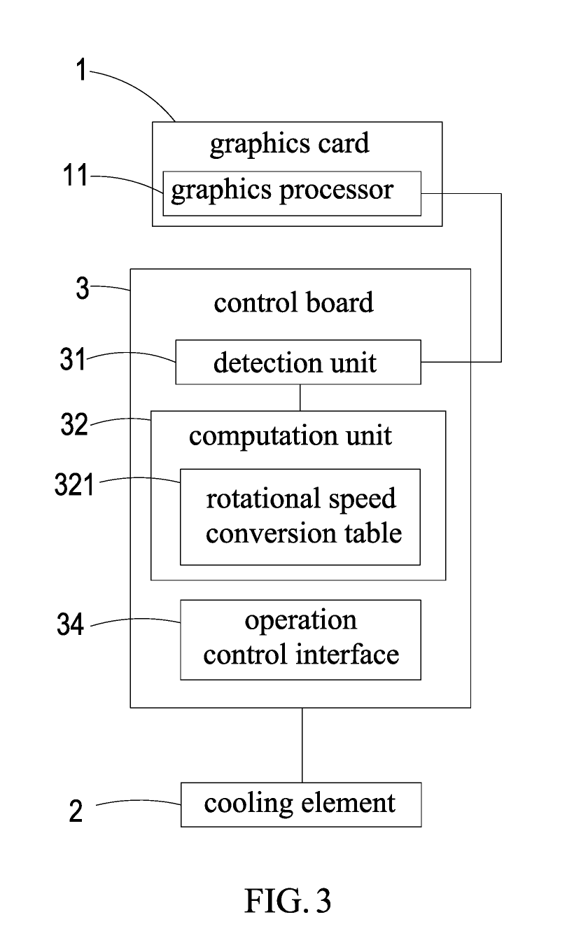

Referring to FIGS. 1-3, which are respectively a perspective view showing a preferred embodiment of the present invention, an exploded view of the preferred embodiment of the present invention, and a structure block diagram of the preferred embodiment of the present invention, it is clearly seen from the drawings that the present invention comprises:

a graphics card 1, where the graphics card 1 is provided thereon with at least one graphics processor 11;

at least one cooling element 2 that is arranged at one side of the graphics card 1 for cooling the graphics card 1;

at least one control board 3 that is arranged at one side of the cooling element 2 and in electrical connection with the cooling element 2 for controlling an operation speed of the cooling element 2, wherein the control board 3 is provided therein with at least one detection unit 31, and the detection unit 31 comprises software for reading and accessing chip specification of the graphics processor 11 and detecting a power consumption parameter of the graphics processor 11;

at least one computation unit 32 that is arranged in the control board 3 and in information communication with the detection unit 31, wherein the computation unit 32 comprises software for integrating the chip specification and the power consumption parameter to generate the operation speed, and the computation unit 32 comprises at least one rotational speed conversion table 321; and

an operation control interface 34 arranged in the control board, wherein the operation control interface 34 is in information communication with the detection unit 31 and the computation unit 32.

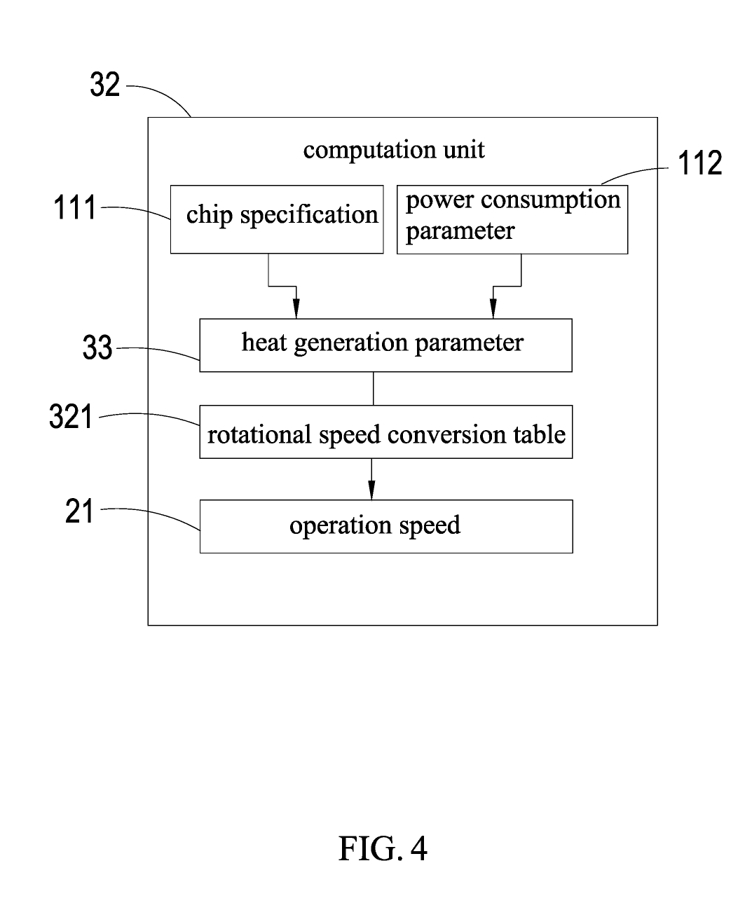

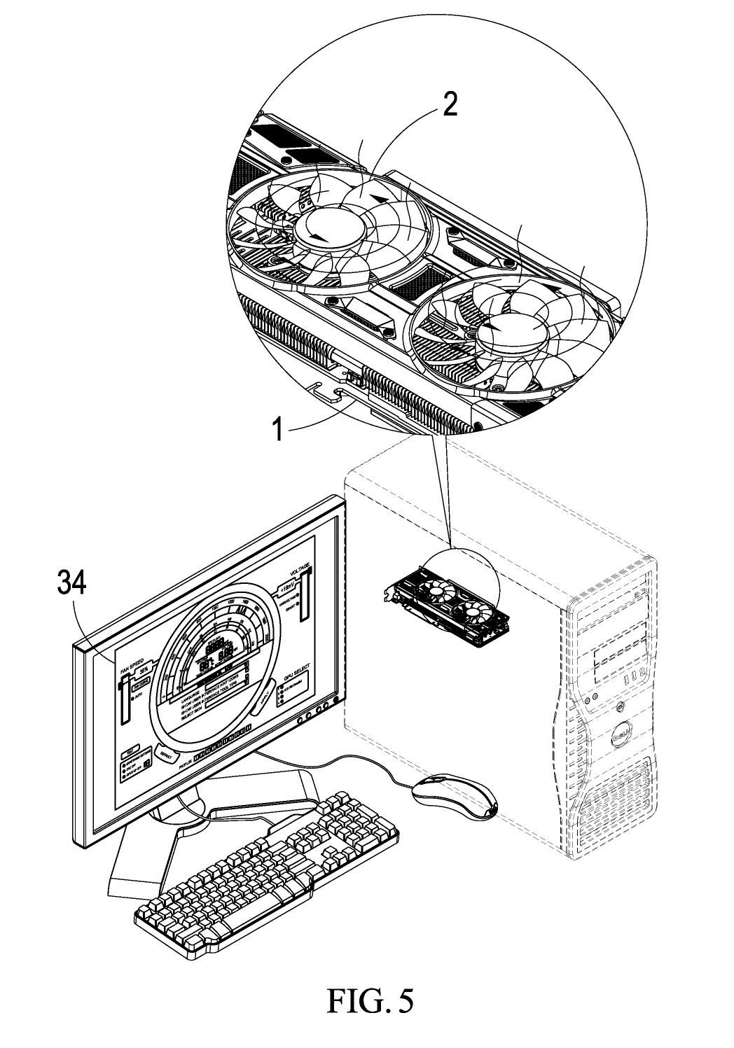

Referring collectively to FIGS. 1-5, which are respectively a perspective view showing a preferred embodiment of the present invention, an exploded view of the preferred embodiment of the present invention, a structure block diagram of the preferred embodiment of the present invention, a schematic view illustrating an operation of a computation unit of the preferred embodiment of the present invention, and a schematic view showing an application of the preferred embodiment of the present invention, it can be clearly seen from the drawings that when the graphics card 1 is put into operation, the graphics card 1 generate heat and an operation of the cooling element 2 lower down a temperature of the graphics card 1 so that the graphics card 1 does not get down due to an excessively high temperature. In the embodiment, the cooling element 2 comprises a fan. The graphics processor 11 (which can be for example a graphics processing unit, GPU) of the graphics card 1 is an important component that performs operations of graphics computation. The operation of the graphics processor 11 consumes quite a tremendous amount of electrical energy and the operation also creates a very large amount of heat. The chip specification 111 and the power consumption parameter 112 of the graphics processor 11 may serve as an index of heat amount generated by the graphics card 1. The chip specification 111 generally includes the power specification of the graphics processor 11, and the power consumption parameter 112 can be one of voltage and frequency. To allow the cooling element 2 to efficiently dissipate heat from the graphics card 1, a user may use a computer to operate the operation control interface 34, and the operation control interface 34 may comprise software and the operation control interface 34 may be operated to activate the detection unit 31 to read and access the chip specification 111 of the graphics processor 11 and to detect the power consumption parameter 112 of the graphics processor 11. The detection unit 31 transmits the chip specification 111 and the power consumption parameter 112 to the computation unit 32, so that the computation unit 32 may convert the chip specification 111 and the power consumption parameter 112 into a heat generation parameter 33, and to further the heat generation parameter 33, through a rotational speed conversion table 321, into an optimum operation speed 21 of the cooling element 2, and the user is allowed to inspect, through the operation control interface 34, the operation speed 21, so that if the user wishes to adjust and set the cooling element 2 to the operation speed 21, the user may the operation control interface 34 to control the control board 3 to make the control board 3 to adjust and set the cooling element 2 to the operation speed 21, making the cooling element 2 provide an optimum or best performance of heat dissipation from the graphics card 1.

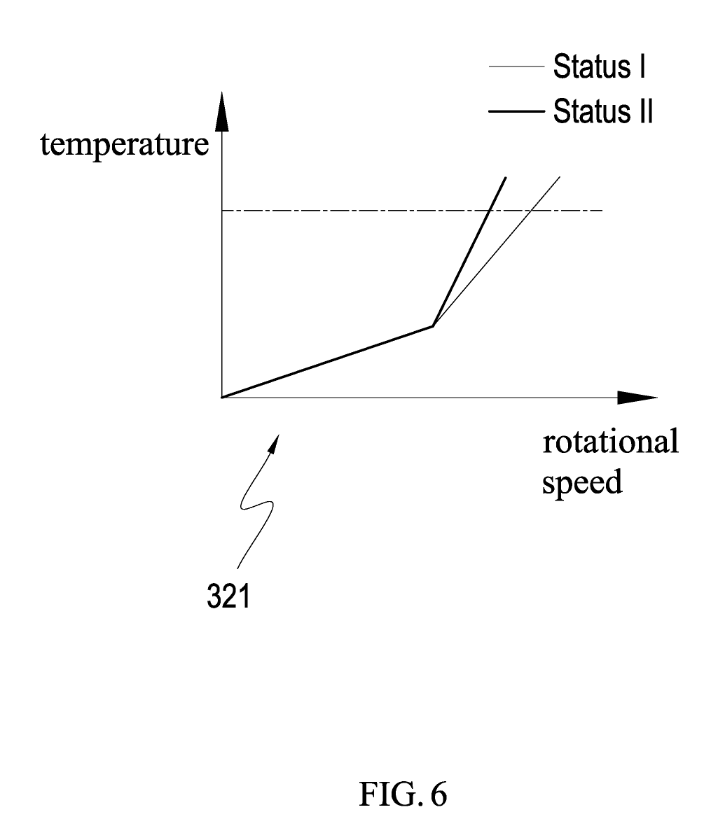

Referring to FIG. 6, which is a plot demonstrating rotational speed conversion conducted according the preferred embodiment of the present invention, the drawing clearly shows that Status I and Status II of the rotational speed conversion table 321 indicate graphics processors of the same model but having different heat generation parameters, or graphics processors of different models, in which Status I represents a high power consumption status of a graphics processor and thus the rotational speed of the fan must be increased to keep the graphics processor at a steady temperature, and Status II represents a low power consumption status of a graphics processor and a low rotational speed of the fan is sufficient for lowering down the temperature to keep the graphics processor at a steady temperature.

The example provided previously is concerned about just a preferred way of embodying the present invention and is not intended to impose limitations to the scope of the present invention. Minor modifications and variations that do not depart from the inventive idea of the present invention as defined in the attached claims, are considered within the scope of the present invention.

Thus, with reference to all the drawings, when put into use, the present invention provides, compared to the prior art, the following advantages:

(1) The arrangement of the detection unit 31 and the computation unit 32 allows for reading and accessing a difference of the chip specification 111 of a graphics processor 11 provided on a graphics card 1 and for detecting the power consumption parameter 112 of operation of the graphics processor 11 and also allows for integration of the chip specification 111 and the power consumption parameter 112 to generate an optimum operation speed 21 of the cooling element 2.

(2) The arrangement of the control board 3 and the cooling element 2 makes it possible to conduct efficient dissipation of heat from a graphics card 1 by adjusting the cooling element 2 according to the optimum operational speed 21 of the cooling element 2 generated by the computation unit 32.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I claim:

1. A heat dissipation control device based on graphics card core parameters, comprising:
a graphics card;
at least one cooling element arranged at one side of the graphics card for cooling the graphics card;
at least one control board arranged at one side of the cooling element and in electrical connection with the cooling element for controlling an operation speed of the cooling element;
at least one graphics processor provided on the graphics card;
at least one detection unit provided in the control board to read and access chip specification of the graphics processor and to detect a power consumption parameter of the graphics processor; and
at least one computation unit arranged in the control board and in information communication with the detection unit to integrate the chip specification and the power consumption parameter to generate the operation speed.

2. The heat dissipation control device based on graphics card core parameters according to claim 1, wherein the power consumption parameter comprises one of a voltage and a frequency.

3. The heat dissipation control device based on graphics card core parameters according to claim 1, wherein the cooling element comprises a fan.

4. The heat dissipation control device based on graphics card core parameters according to claim 1, wherein the computation unit comprises at least one rotational speed conversion table.

5. The heat dissipation control device based on graphics card core parameters according to claim 4, wherein the computation unit converts the chip specification and the power consumption parameter into a heat generation parameter and the heat generation parameter is converted through the rotational speed conversion table into the operation speed.

6. The heat dissipation control device based on graphics card core parameters according to claim 1, wherein the chip specification comprises power specification of the graphics processor.

7. The heat dissipation control device based on graphics card core parameters according to claim 1, wherein the control board is provided therein with an operation control interface, and the operation control interface is in information communication with the detection unit and the computation unit.

8. The heat dissipation control device based on graphics card core parameters according to claim 1, wherein the detection unit comprises software.

9. The heat dissipation control device based on graphics card core parameters according to claim 1, wherein the computation unit comprises software.
